(19) United States
(12) Patent Application Publication
(10) Pub. No.: US 2023/0137503 A1
(43) Pub. Date: May 4, 2023

(54) ELECTROMAGNETICALLY TRANSPARENT METALLIC-LUSTER MEMBER AND METHOD FOR PRODUCING THE SAME

(71) Applicant: NITTO DENKO CORPORATION, Ibaraki-shi, Osaka (JP)

(72) Inventors: Xiaolei CHEN, Ibaraki-shi, Osaka (JP); Taichi WATANABE, Ibaraki-shi, Osaka (JP); Hironobu MACHINAGA, Ibaraki-shi, Osaka (JP); Kazuto YAMAGATA, Ibaraki-shi, Osaka (JP)

(21) Appl. No.: 17/910,428

(22) PCT Filed: Mar. 8, 2021
(86) PCT No.: PCT/JP2021/008949

§ 371 Date: Sep. 9, 2022

(30) Foreign Application Priority Data
Mar. 9, 2020 (JP) 2020-040058

(51) Int. Cl. C23C 14/08; C23C 14/20; C23C 14/34; C23C 14/04

(52) U.S. Cl. CPC C23C 14/086; C23C 14/20; C23C 14/34; C23C 14/04

(57) ABSTRACT

The present invention relates to an electromagnetically transparent metallic-luster member including a base and a metal layer formed over the base, wherein the metal layer includes a plurality of portions which are at least partly discontinuous and separate from each other, the metal layer includes a portion including aluminum element and a portion including indium element, the portion including indium element localizes in the metal layer, and a volume content (vol %) of the portion including indium element in the metal layer is 5-40 vol %.

### TECHNICAL FIELD

The present invention relates to an electromagnetically transparent metallic-luster member and a method for producing the metallic-luster member.

### BACKGROUND ART

Nowadays, members having electromagnetic transparency and a metallic luster are favorably used in devices for sending/receiving electromagnetic waves, because these members combine a high-grade appearance attributable to the metallic luster and electromagnetic transparency.

In case where a metal is used as or in a metallic-luster member, this member may make the transmission of electromagnetic waves substantially impossible or may obstruct it. Because of this, an electromagnetically transparent metallic-luster member having both a metallic luster and electromagnetic transparency is desired for maintaining intact design attractiveness without obstructing the transmission of electromagnetic waves.

Such electromagnetically transparent metallic-luster members are expected to be used in application to devices in which electromagnetic waves are sent/received, such as various appliances required to communicate, e.g., door handles of a motor vehicle equipped with a smart key and electronic appliances including vehicle-mounted communication appliances, cell phones, and personal computers. Furthermore, with the recent progress of IoT technology, the electromagnetically transparent metallic-luster members are expected to be used also in a wide range of fields including the fields of domestic electrical appliances, e.g., refrigerators, and household appliances which have not hitherto performed communication or the like.

With respect to electromagnetically transparent metallic-luster members, Patent Document 1 describes an electromagnetically transparent metallic-luster member which includes an indium-oxide-containing layer formed on a surface of a base and a metal layer superposed on the indium-oxide-containing layer and which is characterized in that the metal layer includes a plurality of portions that are at least partly discontinuous and separate from each other.

### CITATION LIST

### Patent Literature

Patent Document 1: JP-A-2018-69462

### SUMMARY OF INVENTION

### Technical Problem

The electromagnetically transparent metallic-luster member has had a problem in that in cases when the metallic-luster member is bent and stretched in producing a 3D shaped object, portions thereof which are stretched to a high degree suffer cracks to become opaque or discolored. This is because the metal layer, when having been formed through an undercoat layer such as an indium-oxide-containing layer, has cracks due to the undercoat layer. The occurrence of cracks and the opacification or discoloration impair the metallic luster, making it impossible to attain both satisfactory electromagnetic transparency and glittering properties.

An object of the present invention, which has been achieved in order to overcome that problem, is to provide an electromagnetically transparent metallic-luster member which has excellent electromagnetic transparency and glittering properties and is inhibited from suffering cracks due to stretching and from being opacified or discolored by such cracks.

### Solution to the Problem

The present inventors diligently made investigations in order to overcome the problem and, as a result, have discovered that the problem can be eliminated by discontinuously disposing on a base a metal layer which includes a portion including aluminum element and a portion including indium element and in which the portion including indium element localizes in the metal layer and the volume content of the portion including indium element is in a specific range. The present invention has been thus completed.

That is, the present invention is as follows.

[1]

An electromagnetically transparent metallic-luster member including a base and a metal layer formed over the base, wherein

the metal layer includes a plurality of portions which are at least partly discontinuous and separate from each other,

the metal layer includes a portion including aluminum element and a portion including indium element,

the portion including indium element localizes in the metal layer, and a volume content (vol %) of the portion including indium element in the metal layer is 5-40 vol %.

[2]

The electromagnetically transparent metallic-luster member according to [1] above wherein the portion including indium element localizes in the metal layer on the side opposite from the base.

[3]

The electromagnetically transparent metallic-luster member according to [1] or [2] above wherein the metal layer has a thickness of 10-200 nm.

[4]

The electromagnetically transparent metallic-luster member according to any one of [1] to [3] above wherein the plurality of portions have been formed in an island arrangement.

[5]

The electromagnetically transparent metallic-luster member according to any one of [1] to [4] above wherein the base is a substrate film, a molded-resin substrate, or an article to which a metallic luster is to be imparted.

[6]

The electromagnetically transparent metallic-luster member according to any one of [1] to [5] above wherein the metal layer, when the metallic-luster member is subjected to a tensile test with an elongation of 20%, has a crack width of 150 nm or less.

[7]

The electromagnetically transparent metallic-luster member according to any one of [1] to [6] above which, when subjected to a tensile test with an elongation of 20%, has a Y value (SCE) of 0.3 or less, the Y value being measured with a spectral colorimeter in accordance with JIS Z 8722, geometrical conditions c.

[8]

A method for producing the electromagnetically transparent metallic-luster member according to any one of [1] to [7] above, the method including

a first step, in which a layer including a plurality of portions that at least include indium element and are at least partly discontinuous and separate from each other is formed over a base, and

a second step, in which one or more metals including aluminum element are vapor-deposited on the layer formed in the first step.

[9]

The method according to [8] above wherein in the first step, the layer is formed by sputtering in an atmosphere containing substantially no oxygen.

### Advantageous Effect of the Invention

The present invention can provide an electromagnetically transparent metallic-luster member which has excellent electromagnetic transparency and glittering properties and is inhibited from suffering cracks due to stretching and from being opacified or discolored by such cracks.

### BRIEF DESCRIPTION OF DRAWINGS

FIG. 1A is a diagrammatic cross-sectional view of an electromagnetically transparent metallic-luster member 1 according to one embodiment of the present invention.

FIG. 1B is a diagram showing an electron photomicrograph (SEM image) of a surface of the electromagnetically transparent metallic-luster member 1 according to one embodiment of the present invention.

FIG. 2A shows an example of electron photomicrographs (TEM images) of cross-sections of the electromagnetically transparent metallic-luster member 1 according to one embodiment of the present invention.

FIG. 2B is a diagram showing an enlarged photograph of the metal layer of FIG. 2(a).

FIG. 3 is a diagram for illustrating a method for determining the thickness of the metal layer of an electromagnetically transparent metallic-luster member according to one embodiment of the present invention.

FIG. 4A is a diagram of photographs showing distributions of In, Al, and O elements obtained in an elemental analysis of the electromagnetically transparent metallic-luster member of Example 1.

FIG. 4B is a diagram of photographs showing distributions of In, Al, and O elements obtained in an elemental analysis of the electromagnetically transparent metallic-luster member of Comparative Example 4.

FIG. 5A is a diagram of an electron photomicrograph (SEM image) of a surface of the electromagnetically transparent metallic-luster member of Example 1 which had not been stretched.

FIG. 5B is a diagram of an electron photomicrograph (SEM image) of the surface of the electromagnetically transparent metallic-luster member of Example 1 which had been stretched.

FIG. 6A is a diagram of an electron photomicrograph (SEM image) of a surface of the electromagnetically transparent metallic-luster member of Comparative Example 4 which had not been stretched.

FIG. 6B is a diagram of an electron photomicrograph (SEM image) of the surface of the electromagnetically transparent metallic-luster member of Comparative Example 4 which had been stretched.

### DESCRIPTION OF EMBODIMENTS

An electromagnetically transparent metallic-luster member according to an embodiment of the present invention includes a base and a metal layer formed over the base, wherein the metal layer includes a plurality of portions which are at least partly discontinuous and separate from each other, the metal layer includes a portion including aluminum element and a portion including indium element, the portion including indium element localizes in the metal layer, and a volume content (vol %) of the portion including indium element in the metal layer is 5-40 vol %.

The present invention will be described in detail below using the accompanying drawings for reference. However, the present invention is not limited to the following embodiments and can be modified at will unless the modifications depart from the gist of the present invention. Furthermore, “-” indicating a numerical range is used in such a sense that the numerical values given before and after the “-” are included as a lower limit value and an upper limit value.

### <1. Basic Configuration>

The electromagnetically transparent metallic-luster member according to an embodiment of the present invention includes a base and a metal layer formed over the base, and the metal layer includes a plurality of portions which are at least partly discontinuous and separate from each other.

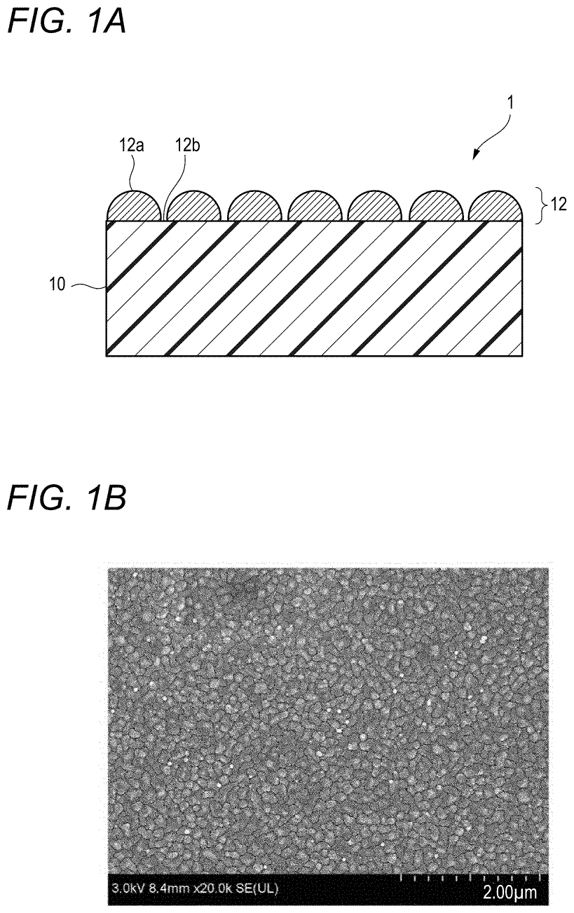

FIG. 1A shows a diagrammatic cross-sectional view of an electromagnetically transparent metallic-luster member 1 according to one embodiment of the present invention, and FIG. 1B shows an example of electron photomicrographs (SEM images) of a surface of the electromagnetically transparent metallic-luster member 1 according to one embodiment of the present invention. In the electron photomicrograph, the image size is 6.25 μm×4.65 μm.

As FIG. 1A shows, the electromagnetically transparent metallic-luster member 1 includes a base 10 and a metal layer 12 formed over the base 10.

It is preferable that the discontinuous-state metal layer 12 has been formed on the base 10 and that the electromagnetically transparent metallic-luster member 1 has no undercoat layer formed between the base 10 and the metal layer 12. The absence of any undercoat layer between the base 10 and the metal layer 12 can inhibit the occurrence of cracks due to the cracking of an undercoat layer caused by stretching. A layer which is less causative of cracks (e.g., a protective layer) may have been disposed between the base 10 and the metal layer 12. This will be explained in detail later in <4. Other Layers>.

The metal layer 12 includes a plurality of portions 12a. These portions 12a are at least partly in a discontinuous state, in other words, are at least partly separate from each other by gaps 12b. Because of the separation by gaps 12b, these portions 12a have an increased sheet resistance and reduced interaction with radio waves and can hence transmit the radio waves. Each of these portions 12a is an aggregate of sputter particles formed by vapor-depositing metals. In cases when such sputter particles form a thin film on a base, e.g., the base 10, the diffusibility of the particles on the surface of the base affects the shape of the thin film.

The term “discontinuous state” as used herein means a state in which the portions 12 are separate from each other by gaps 12b and, as a result, have been electrically insulated from each other. The electrical insulation has resulted in an increased sheet resistance to obtain the desired electromagnetic transparency. Discontinuous structures are not particularly limited, and examples thereof include an island arrangement and a cracked structure.

FIG. 1B is an electron photomicrograph (SEM image) of the surface of the metal layer of the electromagnetically transparent metallic-luster member 1. The term “island arrangement” means, as shown in FIG. 1B, a structure composed of independent particles which each are an aggregate of sputter particles and which have been spread all over the surface so as to be slightly separate from each other or partly in contact with each other.

The cracked structure is a structure in which the thin metal film has been divided by cracks. This cracked structure is different from the above-described cracks caused by stretching.

The metal layer 12 having a cracked structure can be formed, for example, by disposing a thin metal film layer on a base and bending or stretching the coated base to cause the thin metal film layer to crack. In doing so, the formation of the metal layer 12 having a cracked structure can be facilitated by disposing a brittle layer made of a poorly stretchable material, i.e., a material which is apt to crack upon stretching, between the base and the thin metal film layer.

Although the state in which the metal layer 12 is discontinuous is not particularly limited as mentioned above, an “island arrangement” is preferred from the standpoint of production efficiency.

The electromagnetic transparency of the electromagnetically transparent metallic-luster member 1 can be evaluated, for example, in terms of the attenuation of radio-wave transmission. The attenuation of radio-wave transmission can be measured, for example, by the method which will be described later in Examples.

Specifically, the attenuation of radio-wave transmission at 28 GHz can be evaluated using a KEC-method measuring/evaluation jig and spectral analyzer CXA signal Analyzer NA9000A, manufactured by Agilent Inc. There is a correlation between electromagnetic transparency in a millimeter-wave radar frequency band (76-80 GHz) and electromagnetic transparency in a microwave band (28 GHz), and relatively close values are shown. Hence, the electromagnetic transparency in the microwave band (28 GHz), i.e., the attenuation of microwave electric-field transmission, is used as an index.

The attenuation of radio-wave transmission in the microwave band (28 GHz) is preferably 1 [−dB] or less, more preferably 0.3 [−dB] or less, still more preferably 0.1 [−dB] or less. By regulating the attenuation of radio-wave transmission in the microwave band (28 GHz) to 1 [−dB] or less, the problem wherein 20% or more of radio waves are cut off can be avoided.

The glittering properties (appearance) of the electromagnetically transparent metallic-luster member 1 can be evaluated, for example, by measuring a Y value (SCI), a Y value (SCE), a b* value, etc. The Y value (SCI), Y value (SCE), and b* value can be measured using a spectral colorimeter in accordance with JIS Z 8722, geometrical conditions c.

In the case where the metallic-luster member is evaluated for glittering property (appearance) after stretching, the member is evaluated, for example, after a tensile test is performed using a tensile tester under the conditions of 150° C., a stretching speed of 5 mm/min, and an elongation of 20%.

The larger the Y value (SCI) after the tensile test, the more the decrease in glittering property due to the stretching was able to be reduced. The Y value (SCI) after the tensile test is preferably 40 or larger, more preferably 50 or larger, still more preferably 55 or larger. In cases when the Y value (SCI) is 40 or larger, this metallic-luster member has satisfactory glittering properties and an excellent appearance.

Meanwhile, the smaller the Y value (SCE) after the tensile test, the more the opacification due to the stretching was able to be inhibited. The Y value (SCE) after the tensile test is preferably 1 or smaller, more preferably 0.3 or smaller, still more preferably 0.1 or smaller. In cases when the Y value (SCE) is 1 or smaller, this metallic-luster member has an excellent appearance with reduced opacity.

*b value indicates the intensity of colors ranging from blue to yellow. Values of b* not larger than −4 before the tensile test are undesirable because the color is bluish. Values of b* not smaller than 4 before the tensile test are undesirable because the color is yellowish.

The b* value after the tensile test is preferably smaller than 4, more preferably smaller than 3, still more preferably smaller than 2. In cases when the b* value after the tensile test is smaller than 4, this metallic-luster member was able to be inhibited from becoming yellowish due to the stretching and has an excellent appearance with a natural color (silver). Meanwhile, the b* value after the tensile test is preferably −1 or larger. In cases when the b* value after the tensile test is −1 or larger, this metallic-luster member was able to be inhibited from becoming bluish due to the stretching and has an excellent appearance with a natural color (silver).

The stretchability of the electromagnetically transparent metallic-luster member 1 can be evaluated by measuring the width of cracks of the metal layer after a tensile test. The tensile test is conducted, for example, by the same method as for the glittering properties (appearance). The smaller the crack width of the metal layer after the tensile test, the more the occurrence of cracks due to the stretching was able to be inhibited and the better the resistance to stretching. The crack width of the metal layer after the tensile test is preferably 170 nm or less, more preferably 160 nm or less, still more preferably 150 nm or less.

### <2. Base>

Examples of the base 10, from the standpoint of electromagnetic transparency, include substrate films, molded-resin substrates, or articles to which a metallic luster is to be imparted.

More specifically, as the substrate films, use can be made of transparent films made of homopolymers and copolymers such as, for example, poly(ethylene terephthalate) (PET), poly(ethylene naphthalate) (PEN), poly(butylene terephthalate), polyamides, poly(vinyl chloride), polycarbonates (PC), cycloolefin polymers (COP), polystyrene, polypropylene (PP), polyethylene, polycycloolefins, polyurethanes, acrylics (PMMA), and ABS.

These members do not affect the glittering properties or the electromagnetic transparency. However, from the standpoint of later forming the metal layer 12, materials which can withstand high temperatures during vapor deposition, etc. are preferred. Because of this, preferred of those materials are, for example, poly(ethylene terephthalate), poly(ethylene naphthalate), acrylics, polycarbonates, cycloolefin polymers, ABS, polypropylene, and polyurethanes. Preferred of these are poly(ethylene terephthalate), cycloolefin polymers, polycarbonates, and acrylics, because these materials have a good balance between heat resistance and cost.

The substrate film may be either a single-layer film or a multilayer film. From the standpoints of processability, etc., the thickness thereof is, for example, preferably about 6-250 μm. The substrate film may have undergone a plasma treatment, adhesion-promoting treatment, or the like for enhancing the strength of adhesion to the metal layer 12. The substrate film preferably contains no particles.

Here, it should be noted that the substrate film is a mere example of the substance of interest (base 10) that has a surface over which the metal layer 12 can be formed. As stated above, the base 10 may be a molded-resin substrate or an article itself to which a metallic luster is to be imparted, besides being the substrate film. Examples of the molded-resin substrate and the article to which a metallic luster is to be imparted include structural components for vehicles, articles for mounting on vehicles, the housings of electronic appliances, the housings of domestic electrical appliances, structural components, machine components, various automotive components, components for electronic appliances, uses for household goods such as furniture and kitchen utensils, medical appliances, components for building materials, and other structural components and exterior components.

### <3. Metal Layer>

The metal layer 12 is formed over the base 10. As stated above, the metal layer 12 may have been disposed directly on a surface of the base 12, or may have been disposed indirectly through a layer, e.g., a protective layer, that has been disposed on the surface of the base 10 and is less apt to cause cracks upon stretching. The metal layer 12 is a layer having a metallic appearance and is preferably a layer having a metallic luster.

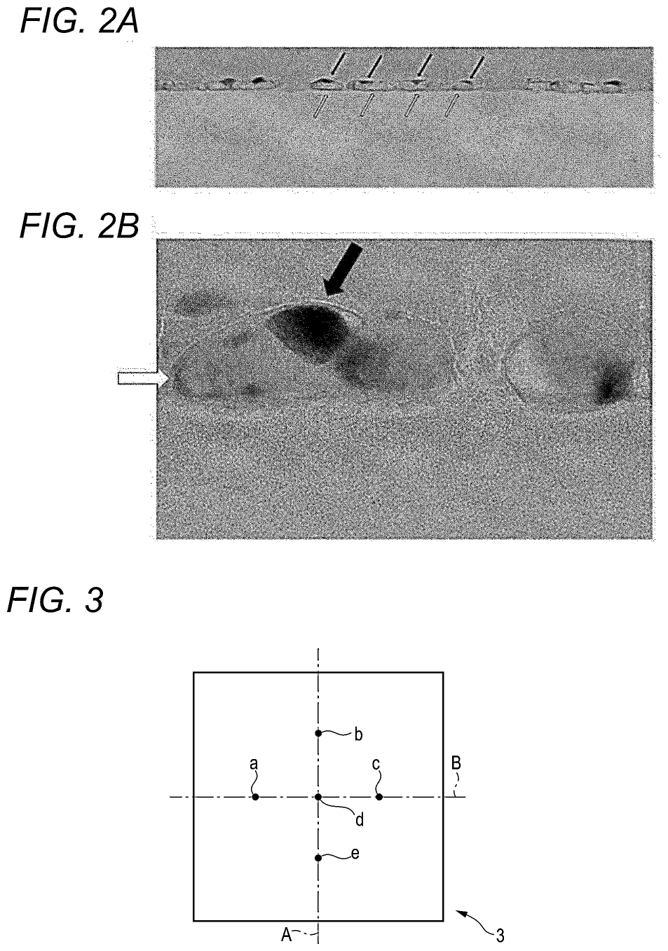

The metal layer 12 includes portions including aluminum element and portions including indium element. As the open arrows in FIGS. 2A and 2B show, the portions including aluminum element usually occupy major regions of the metal layer 12. One or more portions including aluminum element and one or more portions including indium element are included in the same metal layer. When explained using FIG. 1A, this means that both a portion including aluminum element and a portion including indium element are included in at least one portion 12a. Incidentally, any configuration in which a portion including aluminum element and a portion including indium element are present in different metal layers and are not both included in the same metal layer, such as, for example, a case where the portions 12a are ones formed by superposing a metal layer including aluminum element and a metal layer including indium element, is not included in embodiments of the present invention.

In the metal layer 12, the volume content (vol %) of the portions including aluminum element is preferably 60 vol % or higher, more preferably 75 mol % or higher, still more preferably 90 vol % or higher. In cases when the volume content of the portions including aluminum element in the metal layer 12 is 60 vol % or higher, sufficient glittering properties can be rendered possible and the metallic-luster member can have a natural color.

The portions including aluminum element, besides being required, as a matter of course, to include aluminum and be capable of exhibiting sufficient glittering properties, preferably contains a substance having a relatively low melting point. This is because the portions including aluminum element are preferably formed by thin-film growth by vapor deposition. For such reason, suitable for use in the portions including aluminum element are metals having melting points of about 1,000° C. or lower. For example, the portions including aluminum element may contain at least one metal selected from among zinc (Zn), lead (Pb), copper (Cu), and silver (Ag) or an alloy including said metal as a main component.

The portions including aluminum element are not particularly limited in how these portions are included in the metal layer. It is, however, preferable that at least some of the portions including aluminum element are in contact with the base (or in contact with another layer in the case where the layer has been disposed on the base). That is, the portions including aluminum element are preferably present on the base side. This enables the metal layer 12 to retain an appearance with high glittering properties when viewed also through the base.

In the metal layer 12, the portions including indium element localize. As the solid arrows in FIGS. 2A and 2B show, the portions including indium element are not evenly present scatteringly in the metal layer 12 but localize in some portions of the metal layer 12. So long as the portions including indium element localize in the metal layer 12, these portions are not particularly limited in how the portions are present. For example, the portions including indium element may localize in the metal layer 12 so as to be surrounded by the portions including aluminum element, or may localize in upper portions of the portions including aluminum element, that is, on the side opposite from the base (in a surface-side region of the metal layer 12), as shown in FIGS. 2A and 2B. Preferred of these is that the portions including indium element localize on the side opposite from the base. This enables the metal layer 12 to retain an appearance with high glittering properties when viewed also through the base.

Such metal layer 12 in which the portions including indium element localize is obtained in the following manner as will be explained later in <5. Method for producing the Electromagnetically Transparent Metallic-luster Member>. First, a layer including a plurality of portions which include indium element and are at least partly discontinuous and separate from each other is formed on a base 10. Subsequently, a metallic target material including aluminum element is used to conduct vapor deposition on the formed discontinuous layer. Thus, a metal layer 12 in which portions including indium element localize is obtained. Although the reason for the metal layer 12 being thus obtained has not been elucidated, it is presumed to be as follows.

After the discontinuous layer has been formed on the base 10, a metallic target material including aluminum element is used to conduct vapor deposition (e.g., film formation by sputtering) on the discontinuous layer. As a result, the one or more metals including aluminum element continuously grow on the discontinuous layer which is kept retaining the discontinuous shape, and an aluminum-containing layer is formed on the discontinuous layer. As the film thickness and energy of the aluminum-containing layer which is being gradually formed by the vapor deposition (e.g., film formation by sputtering) increase, the low-melting-point metals, including indium, contained in the discontinuous layer are melted. The metals contained in the discontinuous layer and the metals contained in the aluminum-containing layer have poor wettability by each other, and the metals, including indium, contained in the discontinuous layer have a low surface energy. Because of this, the metals, including indium, contained in the discontinuous layer shift into the aluminum-containing layer or to the surface thereof. It is presumed that as a result, the metals including indium are taken up by the aluminum-containing layer, and a metal layer 12 in which portions including aluminum element and portions including indium element are present in the same metal layer and in which the portions including indium element localize is directly formed on the base.

In the metal layer 12, the volume content (vol %) of the portions including indium element is 5-40 vol %. Since the volume content thereof is 5 vol % or higher, the metallic-luster member can be inhibited from becoming opaque through stretching. Furthermore, since the volume content thereof is 40 vol % or less, the metallic-luster member can have high glittering properties and a natural color.

The volume content (vol %) of the portions including indium element in the metal layer 12 is 5 vol % or higher, preferably 10 vol % or higher, and is 40 vol % or less, preferably 25 vol % or less.

The volume content (vol %) of the portions including indium element in the metal layer 12 can be determined, for example, by the method which will be explained later in the Examples.

The indium element may be contained not only as elemental indium but also in the form of an indium alloy, without particular limitations. Examples thereof include In—Sn, In—Cr, and In—Zn.

The metal layer 12 may contain portions including, for example, silver (Ag) or chromium (Cr), as portions other than the portions including aluminum element and portions including indium element.

The thickness of the metal layer 12 is usually 7 nm or larger, preferably 10 nm or larger, from the standpoint of enabling the metal layer 12 to exhibit a sufficient metallic luster. Meanwhile, from the standpoints of sheet resistance and electromagnetic transparency, the thickness thereof is usually preferably 200 nm or less. For example, the thickness thereof is more preferably 7-100 nm, still more preferably 10-70 nm. This thickness range is suitable for efficiently forming an even film and enables the molded resin article as a final product to have a satisfactory appearance.

The thickness of the metal layer 12 can be measured, for example, by the method which will be explained in the Examples.

The metal layer 12 is formed over the base 10 and includes a plurality of portions which are at least partly discontinuous and separate from each other. In case where the metal layer 12 is continuous over the base 10, this metallic-luster member has an exceedingly large attenuation of radio-wave transmission although obtaining a sufficient metallic luster, and cannot hence ensure electromagnetic transparency.

For discontinuously forming the metal layer 12 on the base 10, it is preferred to regulate the metal layer 12 so as to have a reduced oxygen concentration. When sputter particles due to the vapor deposition of a metal form a thin film on a base, the diffusibility of the particles on the surface of the base affects the shape of the thin film, and it is thought that the higher the temperature of the base and the lower the wettability of the base by the metal layer and the melting point of the material of the metal layer, the more easily the discontinuous structure is formed. It is thought that the diffusibility of the metal particles on the surface of the base is enhanced by conducting vapor deposition on the base using a sputtering material containing substantially no oxygen or by conducting the vapor deposition in an atmosphere containing substantially no oxygen, making it possible to form the metal layer in a discontinuous state.

An equivalent-circle diameter of the portions 12a of the metal layer 12 is not particularly limited, and is usually about 10-1,000 nm. The term “average particle diameter of the plurality of portions 12a” means an average value of the equivalent-circle diameters of the plurality of portions 12a.

The equivalent-circle diameter of a portion 12a is the diameter of a complete circle equal in area to the portion 12a.

The distance between the portions 12a is not particularly limited, and is usually about 10-1,000 nm.

### <4. Other Layers>

The electromagnetically transparent metallic-luster member 1 according to the embodiment of the present invention may include other layers in accordance with applications, besides the metal layer 12 described above. It is, however, noted that in case where two or more continuous layers are formed on the base 10, stretching is prone to result in the occurrence of cracks in any of the continuous layers. It is hence preferable that in cases when any other layer is to be disposed between the base 10 and the metal layer 12, this layer is one which is less apt to cause cracks.

Examples of other layers include an optical regulation layer (color regulation layer) of, for example, a high-refractive-index material for regulating appearance, e.g., color, a protective layer (layer for abrasion and scratch resistance) for improving the durability, e.g., abrasion and scratch resistance, a barrier layer (anticorrosion layer), an adhesion-promoting layer, a hardcoat layer, an antireflection layer, a light extraction layer, and an antiglare layer.

### <5. Method for Producing the Electromagnetically Transparent Metallic-Luster Member>

A method for producing the electromagnetically transparent metallic-luster member according to this embodiment is characterized by including a first step, in which a layer (hereinafter also referred to simply as “discontinuous layer” or “first layer”) including a plurality of portions that at least include indium element and are at least partly discontinuous and separate from each other is formed on a base, and a second step, in which one or more metals including aluminum element are vapor-deposited on the discontinuous layer. The steps are described in detail below.

### (1) First Step

In this step, a layer including a plurality of portions that at least include indium element and are at least partly discontinuous and separate from each other is formed on a base 10.

The discontinuous layer can be formed, for example, by vapor-depositing one or more metals including indium element on a surface of the base 10. Examples of methods for the vapor deposition include physical vapor deposition methods such as vacuum deposition, sputtering, and ion plating and chemical vapor deposition (CVD) methods such as plasma-assisted CVD, light-assisted CVD, and laser-assisted CVD. Preferred are the physical vapor deposition methods. More preferred examples include sputtering. By this method, an even and thin, discontinuous layer can be formed.

Especially preferred is to form the discontinuous layer by sputtering using a metallic target material containing indium and substantially no oxygen (1 vol % or less). The metallic target material more preferably contains completely no oxygen. The absence of oxygen in the metallic target material can reduce the wettability of the base and accelerates the formation of a discontinuous layer on the base 10. For the same reason, it is preferable that the vapor deposition for forming the discontinuous layer is conducted in an atmosphere containing substantially no oxygen (100 volume ppm or less), and it is more preferred to conduct the vapor deposition in an atmosphere containing completely no oxygen.

The indium element contained in the metallic target material may be not only elemental indium but also in the form of an indium alloy, without particular limitations. Examples thereof include In—Sn, In—Cr, and In—Zn.

The metallic target material may contain silver (Ag), chromium (Cr), etc., besides the metals including indium element.

The sputtering is performed in a vacuum. Specifically, the atmospheric pressure during the sputtering is, for example, 1 Pa or less, preferably 0.7 Pa or less, from the standpoints of inhibiting the sputtering rate from decreasing and of discharge stability, etc.

The power source to be used for the sputtering may be any of, for example, a DC power source, an AC power source, an MF power source, and an RF power source, or may be a combination of two or more of these.

In order to form a discontinuous layer having a desired thickness, sputtering may be conducted multiple times using suitably selected metallic target materials and suitably set sputtering conditions, etc.

### (2) Second Step

Subsequently, one or more metals including aluminum element are vapor-deposited on the formed discontinuous layer. For this vapor deposition, the same vapor deposition methods as in the first step can be employed.

As a metallic target material, use is made of one or more metals including aluminum element. Besides being elemental aluminum, the aluminum element contained in the metallic target material may be in the form of an aluminum compound or an aluminum alloy.

The metallic target material may contain zinc (Zn), lead (Pb), copper (Cu), silver (Ag), etc., besides the metals including aluminum element.

The production method according to this embodiment can form, on a base, a discontinuous metal layer including portions including aluminum element and portions including indium element. As stated hereinabove, this is presumed to be because an aluminum-containing layer grows continuously on a discontinuous layer and, during this growth, metals including indium element that are contained in the discontinuous layer shift into the aluminum-containing layer or to the surface thereof, resulting in a state in which portions including aluminum element and portions including indium element are present in the same metal layer.

### <6. Uses of the Electromagnetically Transparent Metallic-Luster Member>

Since the electromagnetically transparent metallic-luster member according to this embodiment has electromagnetic transparency, it is preferred to use the metallic-luster member in devices or articles for sending/receiving electromagnetic waves and as or in components for these devices or articles. Examples thereof include structural components for vehicles, articles for mounting on vehicles, the housings of electronic appliances, the housings of domestic electrical appliances, structural components, machine components, various automotive components, components for electronic appliances, uses for household goods such as furniture and kitchen utensils, medical appliances, components for building materials, and other structural components and exterior components.

More specifically, examples thereof for vehicles include instrument panels, console boxes, door knobs, door trims, shift levers, pedals, glove boxes, bumpers, bonnets, fenders, trunks, doors, roofs, pillars, seats, steering wheels, ECU boxes, electrical components, components to be mounted around engines, components to be used around driving systems/gears, components for intake/exhaust systems, and components for cooling systems.

More specific examples of the electronic appliances and domestic electrical appliances include domestic electrical products such as refrigerators, washing machines, vacuum cleaners, electronic ovens, air conditioners, illuminators, electric water heaters, TVs, clocks, ventilating fans, projectors, and speakers and electronic/communication appliances such as personal computers, cell phones, smartphones, digital cameras, tablet type PCs, portable music players, portable video game devices, battery chargers, and batteries.

### EXAMPLES

The present invention is described in greater detail below using Examples and Comparative Examples.

Various samples of the electromagnetically transparent metallic-luster member 1 were prepared and, before and after stretching, examined for the attenuation of radio waves for evaluating electromagnetic transparency, for Y value (SCI), Y value (SCE), and b* for evaluating glittering properties (appearance), and for crack width for evaluating stretchability.

The stretching of the samples was conducted by a uniaxial tensile test using tensile tester TG-10kN, manufactured by MinebeaMitsumi Inc. at 150° C. under the conditions of a stretching speed of 5 mm/min and an elongation of 20%. The elongation is shown by the following equation.

Elongation (%)=100×(L−Lo)/Lo

(Lo: sample length before stretching. L: sample length after stretching)

### [Electromagnetic Transparency]

### (1) Attenuation of Radio-Wave Transmission

The attenuation of radio-wave transmission at 28 GHz was evaluated using a KEC-method measuring/evaluation jig and a spectral analyzer (CXA signal Analyzer NA9000A) manufactured by Agilent Inc. There is a correlation between electromagnetic transparency in a millimeter-wave radar frequency band (76-80 GHz) and electromagnetic transparency in a microwave band (28 GHz), and relatively close values are shown. In this evaluation, the electromagnetic transparency in the microwave band (28 GHz), i.e., the attenuation of microwave electric-field transmission, was hence used as an index and the electromagnetic transparency was assessed on the basis of the following criteria.

### <Attenuation of Radio-Wave Transmission Through Stretching>

0.1 [−dB] or less: excellent

larger than 0.1 [−dB] but not larger than 0.3 [−dB]: good

larger than 0.3 [−dB] but not larger than 1 [−dB]: fair

larger than 1 [−dB]: poor

### [Glittering Property (Appearance)]

(2) Y value (SCI), Y value (SCE), b*

Y value (SCI), Y value (SCE), and b* were measured using spectral analyzer CM-2600d, manufactured by Konica Minolta Japan Inc., in accordance with JIS Z 8722, geometrical conditions c. In this evaluation, as values for quantitatively expressing appearance, use was made of Y value (SCI) for quantitatively expressing metallic luster, Y value (SCE) for quantitatively expressing opacity, and b* for quantitatively expressing color. The Y value (SCI), Y value (SCE), and b* were evaluated on the basis of the following criteria.

<Y Value (SCI) after Stretching>

55 or larger: excellent

50 or larger but less than 55: good

40 or larger but less than 50: fair

less than 40: poor

<Y Value (SCE) after Stretching>

0.1 or less: excellent

larger than 0.1 but not larger than 0.3: good

larger than 0.3 but not larger than 1: fair

larger than 1: poor

### <b* Before and After Stretching>

Before-stretching b* is larger than −4 but less than 4 and after-stretching b* is −1 or larger but less than 2: excellent

Before-stretching b* is larger than −4 but less than 4 and after-stretching b* is 2 or larger but less than 3: good

Before-stretching b* is larger than −4 but less than 4 and after-stretching b* is 3 or larger but less than 4: fair

Before-stretching b* is −4 or less or is 4 or larger or after-stretching b* is less than −1 or is 4 or larger: poor

### [Stretchability]

### (3) Crack Width

Crack width was measured with FE-SEM (SU-8000), manufactured by Hitachi High-Technologies Corp., and evaluated on the basis of the following criteria.

<Crack Width after Stretching>

150 nm or less: excellent

larger than 150 nm but not larger than 160 nm: good

larger than 160 nm but not larger than 170 nm: fair

larger than 170 nm: poor

### [Overall Evaluation]

All the evaluation results were excellent: excellent

The poorest of all the evaluation results was good: good

The poorest of all the evaluation results was fair: fair

The poorest of all the evaluation results was poor: poor

The case where the overall evaluation was fair or higher is regarded as acceptable.

### (4) Method for Examining Metal Layer

An FE-TEM examination was conducted using FE-TEM JEM-2800, manufactured by JEOL Ltd., to determine the thickness of the metal layer. Furthermore, EDX analysis (including mapping) was conducted to determine/calculate the overall thickness of the meal layer and the volumes of aluminum and indium contained therein. Thus, the volume contents of portions including Al and portions including In were determined.

### <Thickness of Metal Layer>

Unevenness in the metal layer, specifically the unevenness in thickness of the portions 12a shown in FIG. 1A, was taken into account, and an average of the thicknesses of the portions 12a was taken as the thickness of the metal layer. The thickness of a portion of each portion 12a which is thickest along the direction perpendicular to the base 10 was taken as the thickness of this portion 12a. An average of these thickness values is called “maximum thickness” for reasons of convenience. In FIGS. 2A and 2B are shown examples of electron photomicrographs (TEM images) of cross-sections of an electromagnetically transparent multilayer member.

In determining the maximum thickness, a square region 3 in which each side had a length of 5 cm, such as that shown in FIG. 3, was first appropriately extracted from the metal layer appearing on the surface of an electromagnetically transparent multilayer member such as that shown in FIGS. 2A and 2B A center line A for the vertical sides of the square region 3 and a center line B for the horizontal sides thereof were each divided into four equal portions to thereby obtain five points “a” to “e” in total, which were selected as examination points.

Next, in an image of a cross-section of each of the selected examination points, such as those shown in FIGS. 2A and 2B, a viewing-angle region including about five portions 12a was extracted. The thickness of each of the five portions 12a in each of the five examination points in total, that is, the thicknesses of 25 portions 12a (five portions by five points), was determined, and an average of these was taken as “maximum thickness”.

### <Determination of Volume Contents of Portions Including Al and Portions Including In>

In order to determine the volume contents of portions including Al and portions including In, a TEM-EDX analysis or TEM-EDX mapping was conducted after the film thickness determination to determine the mass concentrations (mass %) of aluminum and indium. Specifically, the mass concentration of aluminum and mass concentration of indium in each of portions corresponding to the 25 portions 12a selected in the metal layer thickness determination were determined, and an average of these concentrations were determined for aluminum and for indium. Thereafter, the mass % was converted to vol % from In density of 7.31 g/cm³ and Al density of 2.70 g/cm³ using the conversion expression [vol %]=[mass %]÷density, thereby calculating the volume content (vol %) of the portions including Al and the volume content (vol %) of the portions including In.

### Example 1

As a substrate film was used an easy-to-form PET film (product No. G931E75; thickness, 50 μm), manufactured by Mitsubishi Chemical Corp. First, an In—Sn alloy target (Sn ratio, 5 mass %) (ITM) was used to form a layer of an In—Sn alloy, as a first layer, on the substrate film by pulsed DC sputtering (150 kHz). The sputtering was conducted in an atmosphere to which no oxygen was supplied. The obtained first layer had a discontinuous structure.

Subsequently, an Al target was used to form a layer including aluminum (Al) as a second layer on the first layer by AC sputtering (AC: 40 kHz). Thereafter, the first layer and the second layer integrated with each other to form a metal layer. Thus, an electromagnetically transparent metallic-luster member of Example 1 was obtained, the metallic-luster member being composed of the substrate film and the metal layer formed thereon.

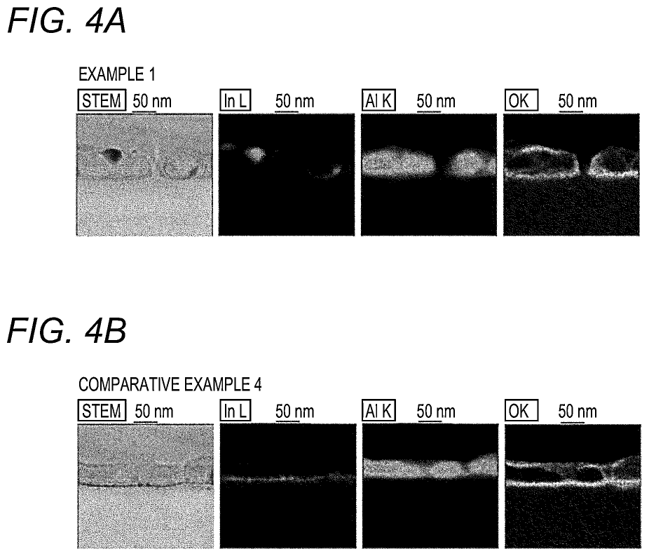

The obtained electromagnetically transparent metallic-luster member of Example 1 was evaluated for various properties, and the results thereof are shown in Table 1. Furthermore, elemental analysis was conducted using FE-TEM JEM-2800, manufactured by JEOL Ltd., to determine distributions of In, Al, and O elements. The results thereof are shown in FIG. 4A.

The obtained metal layer had a discontinuous structure, and portions including aluminum element and portions including indium element were contained in the same metal layer. The portions including indium element localized in the metal layer (on the side opposite from the substrate film).

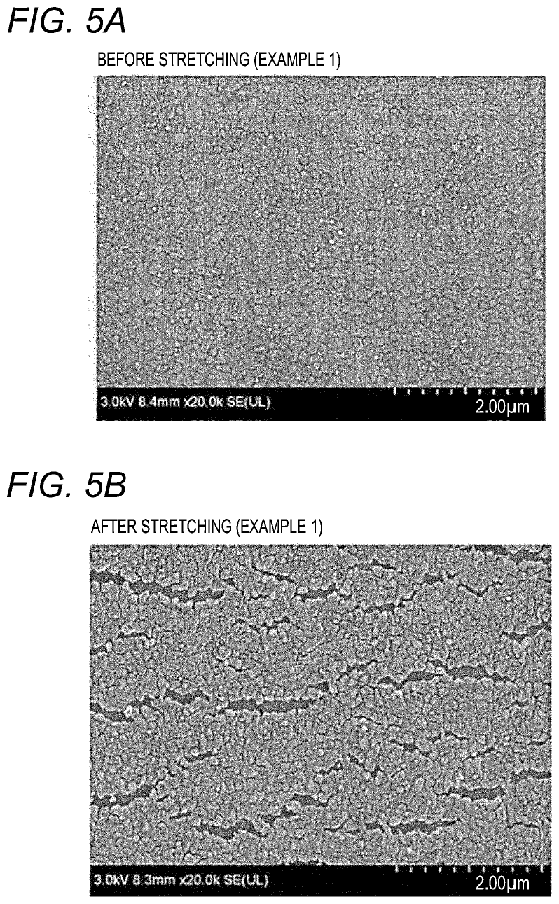

In FIGS. 5A and 5B are shown electron photomicrographs (SEM images) of a surface of the electromagnetically transparent metallic-luster member of Example 1 which had not been stretched and of the surface of the member which had been stretched.

### Example 2

An electromagnetically transparent metallic-luster member of Example 2 was produced and evaluated in the same manners as in Example 1, except that the content (vol %) of portions including Al element in the metal layer and the content (vol %) of portions including indium element (In, Sn) in the metal layer were changed to the values shown in Table 1.

The obtained metal layer had a discontinuous structure, and portions including aluminum element and portions including indium element were contained in the same metal layer. The portions including indium element localized in the metal layer (on the side opposite from the substrate film).

### [Example 3] to [Example 6]

Electromagnetically transparent metallic-luster members of Examples 3 to 6 were produced and evaluated in the same manners as in Example 1, except that the content (vol %) of portions including Al element in the metal layer, the content (vol %) of portions including indium element (In, Sn) in the metal layer, and the film thickness of the metal layer were changed to the values shown in Table 1.

The obtained metal layers each had a discontinuous structure, and portions including aluminum element and portions including indium element were contained in the same metal layer. The portions including indium element localized in the metal layer (on the side opposite from the substrate film).

### Comparative Example 1

An electromagnetically transparent metallic-luster member of Comparative Example 1 was produced and evaluated in the same manners as in Example 1, except that the layer including aluminum (Al) was formed as a first layer and the second layer was omitted to form a metal layer.

### Comparative Example 2

An electromagnetically transparent metallic-luster member of Comparative Example 2 was produced and evaluated in the same manners as in Example 1, except that the content (vol %) of portions including Al element in the metal layer and the content (vol %) of portions including indium element (In, Sn) in the metal layer were changed to the values shown in Table 1.

### Comparative Example 3

An electromagnetically transparent metallic-luster member of Comparative Example 3 was produced and evaluated in the same manners as in Example 1, except that the layer of an In—Sn alloy was formed as a first layer and the second layer was omitted to form a metal layer.

### Comparative Example 4

An electromagnetically transparent metallic-luster member of Comparative Example 4 was produced and evaluated in the same manners as in Example 1, except that a first layer was formed using ITO. In the electromagnetically transparent metallic-luster member of Comparative Example 4, since the first layer was formed using ITO, the first layer and the second layer did not integrate with each other and were formed as two superposed layers (undercoat layer and metal layer) independent of each other. Because of this, in the second layer, the content of portions including Al element was 100 vol % and the content of portions including In element was 0 vol %.

Furthermore, the obtained electromagnetically transparent metallic-luster member of Comparative Example 4 was subjected to elemental analysis using FE-TEM JEM-2800, manufactured by JEOL Ltd., to determine distributions of In, Al, and O elements. The results thereof are shown in FIG. 4B.

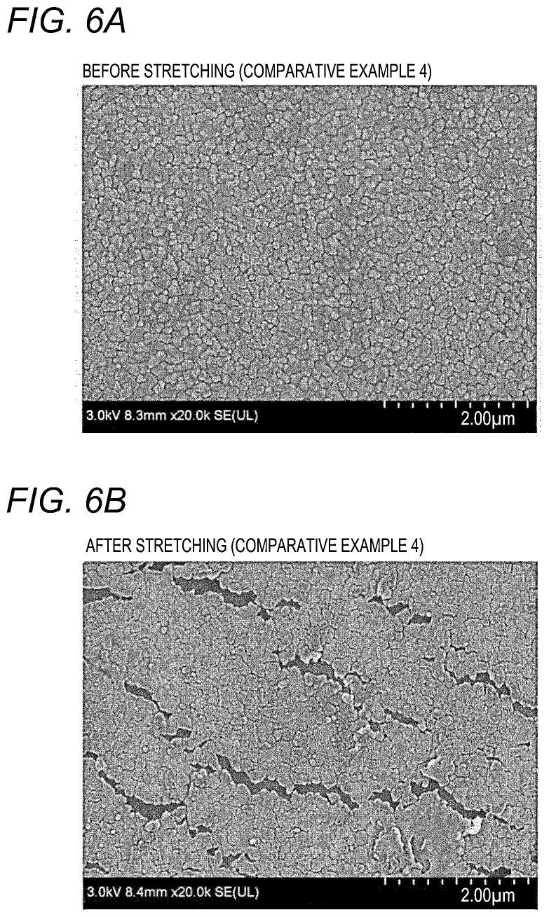

In FIGS. 6A and 6B are shown electron photomicrographs (SEM images) of a surface of the electromagnetically transparent metallic-luster member of Comparative Example 4 which had not been stretched and of the surface of the member which had been stretched.

### [Comparative Example 5] and [Comparative Example 6]

Electromagnetically transparent metallic-luster members of Comparative Examples 5 and 6 were produced and evaluated in the same manners as in Example 1, except that the ITM target was replaced by an In target and that the content (vol %) of portions including Al element in the metal layer, the content (vol %) of portions including indium element (In) in the metal layer, and the film thickness of the metal layer were changed to the values shown in Table 1.

TABLE 1

| | | | | | | | | Radio-wave transparency | |
|---|---|---|---|---|---|---|---|---|---|
| | | | Sputter layer | | | | | Attenuation | |
| | Film deposition conditions | | Undercoat | Metal layer | | | Stretching | of radio-wave | |
| | First layer | Second layer | layer | | Portions | Portions | Uniaxial | transmission | |
| | Sputtering | Sputtering | Thickness | Thickness | including Al | including In | stretching | at 28 GHz | |
| | material | material | [nm] | [nm] | vol % | vol % | [%] | [−dB] | Evaluation |
| Ex. 1 | ITM | Al | 0 | 45 | 90% | 10% | 0 | 0.1 | excellent |
| | | | | | | | 20 | 0.1 | |
| Ex. 2 | ITM | Al | 0 | 45 | 75% | 25% | 0 | 0.1 | excellent |
| | | | | | | | 20 | 0.1 | |
| Ex. 3 | ITM | Al | 0 | 45 | 95% | 5% | 0 | 0.1 | excellent |
| | | | | | | | 20 | 0.1 | |
| Ex. 4 | ITM | Al | 0 | 53 | 70% | 30% | 0 | 0.1 | excellent |
| | | | | | | | 20 | 0.1 | |
| Ex. 5 | ITM | Al | 0 | 45 | 68% | 32% | 0 | 0.1 | excellent |
| | | | | | | | 20 | 0.1 | |
| Ex. 6 | ITM | Al | 0 | 53 | 60% | 40% | 0 | 0.1 | excellent |
| | | | | | | | 20 | 0.1 | |
| Comp. Ex. 1 | Al | none | 0 | 45 | 100% | 0% | 0 | 34.6 | poor |
| | | | | | | | 20 | 25.6 | |
| Comp. Ex. 2 | ITM | Al | 0 | 45 | 55% | 45% | 0 | 0.1 | excellent |
| | | | | | | | 20 | 0.1 | |
| Comp. Ex. 3 | ITM | none | 0 | 45 | 0% | 100% | 0 | 1.6 | fair |
| | | | | | | | 20 | 0.4 | |
| Comp. Ex. 4 | ITO | Al | 5 | 40 | 100% | 0% | 0 | 0.1 | excellent |
| | | | | | | | 20 | 0.1 | |
| Comp. Ex. 5 | In | Al | 0 | 46 | 13% | 87% | 0 | 0.1 | excellent |
| | | | | | | | 20 | 0.1 | |
| Comp. Ex. 6 | In | Al | 0 | 26 | 96% | 4% | 0 | 0.1 | excellent |
| | | | | | | | 20 | 0.1 | |

| | Glittering property (appearance) | | | | | | | | Stretchability | | |
|---|---|---|---|---|---|---|---|---|---|---|---|
| | Y value (SCI) | | Y value (SCE) | | b* | | | | Crack width | | Overall |
| | | Evaluation | | Evaluation | | Evaluation | ΔSCI | ΔSCE | [nm] | Evaluation | evaluation |
| Ex. 1 | 72.4 | excellent | 0.01 | excellent | −0.86 | excellent | −10.5 | 0 | 0 | excellent | excellent |
| | 61.9 | | 0.01 | | 0.49 | | | | 140 | | |
| Ex. 2 | 67.8 | excellent | 0.01 | excellent | −0.7 | excellent | −12.1 | 0 | 0 | excellent | excellent |
| | 55.7 | | 0.01 | | 1.58 | | | | 120 | | |
| Ex. 3 | 71.3 | excellent | 0.01 | fair | −1.73 | excellent | −13.9 | 0.69 | 0 | excellent | fair |
| | 57.4 | | 0.7 | | 0.27 | | | | 150 | | |
| Ex. 4 | 65.3 | excellent | 0.01 | fair | 0.22 | excellent | −8.1 | 0.59 | 0 | excellent | fair |
| | 57.2 | | 0.6 | | 1.12 | | | | 150 | | |
| Ex. 5 | 60.4 | fair | 0.01 | fair | −2.47 | excellent | −12.8 | 0.99 | 0 | good | fair |
| | 47.6 | | 1.0 | | −0.06 | | | | 160 | | |
| Ex. 6 | 57.8 | good | 0.01 | fair | 1.47 | good | −7.1 | 0.59 | 0 | excellent | fair |
| | 50.7 | | 0.6 | | 2.28 | | | | 140 | | |
| Comp. Ex. 1 | 86.4 | excellent | 0.01 | poor | 1.1 | good | −5.6 | 3.32 | 0 | excellent | poor |
| | 80.8 | | 3.33 | | 2.75 | | | | 0 | | |
| Comp. Ex. 2 | 42.5 | poor | 0.01 | fair | 2.8 | good | −7.9 | 0.43 | 0 | excellent | poor |
| | 34.6 | | 0.44 | | 2.79 | | | | 130 | | |
| Comp. Ex. 3 | 59.9 | fair | 0.01 | excellent | 4.73 | poor | −11.2 | 0 | 0 | excellent | poor |
| | 48.7 | | 0.01 | | 5.21 | | | | 80 | | |
| Comp. Ex. 4 | 73.3 | excellent | 0.01 | poor | −1.3 | excellent | −9.7 | 2.73 | 0 | poor | poor |
| | 63.6 | | 2.74 | | 0.48 | | | | 180 | | |
| Comp. Ex. 5 | 50.6 | poor | 0.01 | fair | −4.6 | poor | −11.7 | 0.95 | 0 | good | poor |
| | 38.9 | | 0.96 | | −1.83 | | | | 160 | | |
| Comp. Ex. 6 | 31.6 | poor | 0.01 | excellent | −9.54 | poor | −0.4 | 0 | 0 | excellent | poor |
| | 31.2 | | 0.01 | | −5.45 | | | | 0 | | |

As apparent from Table 1, the electromagnetically transparent metallic-luster members of Examples 1 and 2, even after the stretching, each gave satisfactory results concerning electromagnetic transparency, appearance, and stretchability. Furthermore, these metallic-luster members, after the stretching, had a small crack width and no surface opacity, as can be seen from the after-stretching SEM image (FIG. 5B) of Example 1. The electromagnetically transparent metallic-luster members of Examples 3 to 6 had satisfactory electromagnetic transparency even after the stretching and had satisfactory stretchability. These metallic-luster members each had an appearance on an acceptable level.

Meanwhile, Comparative Examples 1 to 3, 5, and 6, after the stretching, each gave poor evaluation results concerning at least one of electromagnetic transparency, appearance, and stretchability, because the volume content of portions including indium element in the metal layer was outside the range according to the present invention. Comparative Example 4, in which the first layer and the second layer had not integrated with each other and had been formed as two superposed metal layers independent of each other and in which portions including aluminum element and portions including indium element were not contained in the same metal layer, gave poor evaluation results concerning at least one of electromagnetic transparency, appearance, and stretchability after the stretching. Furthermore, as the after-stretching SEM image (FIG. 6B) of Comparative Example 6 shows, the member of Comparative Example 4 had a large crack width after the stretching and had surface opacity.

The present invention is not limited to those Examples and can be practiced after having been suitably modified within the spirit of the present invention.

### INDUSTRIAL APPLICABILITY

The electromagnetically transparent metallic-luster member according to the present invention can be used in devices or articles for sending/receiving electromagnetic waves and as or in components for these devices or articles. This electromagnetically transparent metallic-luster member can be utilized also in various applications where both design attractiveness and electromagnetic transparency are required, such as, for example, structural components for vehicles, articles for mounting on vehicles, the housings of electronic appliances, the housings of domestic electrical appliances, structural components, machine components, various automotive components, components for electronic appliances, uses for household goods such as furniture and kitchen utensils, medical appliances, components for building materials, and other structural components and exterior components.

While the invention has been described in detail and with reference to specific embodiments thereof, it will be apparent to one skilled in the art that various changes and modifications can be made therein without departing from the spirit and scope thereof.

This application is based on a Japanese patent application filed on Mar. 9, 2020 (Application No. 2020-040058), the contents thereof being incorporated herein by reference.

### REFERENCE SIGNS LIST

1 Electromagnetically transparent metallic-luster member
10 Base
12 Metal layer
12a Portion
12b Gap

1. An electromagnetically transparent metallic-luster member comprising a base and a metal layer formed over the base, wherein
the metal layer includes a plurality of portions which are at least partly discontinuous and separate from each other,
the metal layer includes a portion comprising aluminum element and a portion comprising indium element,
the portion comprising indium element localizes in the metal layer, and
a volume content (vol %) of the portion comprising indium element in the metal layer is 5-40 vol %.

2. The electromagnetically transparent metallic-luster member according to claim 1, wherein the portion comprising indium element localizes in the metal layer on the side opposite from the base.

3. The electromagnetically transparent metallic-luster member according to claim 1, wherein the metal layer has a thickness of 10-200 nm.

4. The electromagnetically transparent metallic-luster member according to claim 1, wherein the plurality of portions have been formed in an island arrangement.

5. The electromagnetically transparent metallic-luster member according to claim 1, wherein the base is a substrate film, a molded-resin substrate, or an article to which a metallic luster is to be imparted.

6. The electromagnetically transparent metallic-luster member according to claim 1, wherein the metal layer, when the metallic-luster member is subjected to a tensile test with an elongation of 20%, has a crack width of 150 nm or less.

7. The electromagnetically transparent metallic-luster member according to claim 1, which, when subjected to a tensile test with an elongation of 20%, has a Y value (SCE) of 0.3 or less, the Y value being measured with a spectral colorimeter in accordance with JIS Z 8722, geometrical conditions c.

8. A method for producing the electromagnetically transparent metallic-luster member according to claim 1, comprising
a first step, in which a layer including a plurality of portions that at least comprise indium element and are at least partly discontinuous and separate from each other is formed over a base, and
a second step, in which one or more metals comprising aluminum element are vapor-deposited on the layer formed in the first step.

9. The method according to claim 8, wherein in the first step, the layer is formed by sputtering in an atmosphere containing substantially no oxygen.
